(19) United States
(12) Patent Application Publication
(10) Pub. No.: US 2021/0354311 A1
(43) Pub. Date: Nov. 18, 2021

(54) ROBOT HAND AND ROBOT HAVING THE SAME

(71) Applicant: KAWASAKI JUKOGYO KABUSHIKI KAISHA, Kobe-shi, Hyogo (JP)

(72) Inventors: Takayuki FUKUSHIMA, Kobe-shi (JP); Shogo MATSUOKA, Kakogawa-shi (JP)

(73) Assignee: KAWASAKI JUKOGYO KABUSHIKI KAISHA, Kobe-shi, Hyogo (JP)

(21) Appl. No.: 17/287,644

(22) PCT Filed: Nov. 5, 2019
(86) PCT No.: PCT/JP2019/043207

§ 371 Date: Apr. 22, 2021

(30) Foreign Application Priority Data
Nov. 6, 2018 (JP) 2018-208983

(51) Int. Cl. B25J 15/00; H01L 21/687; H01L 21/677

(52) U.S. Cl. CPC B25J 15/0028; B25J 15/0038; H01L 21/677; H01L 21/68707

(57) ABSTRACT

A robot hand configured to grip a substrate by contacting an edge of the substrate at at least two locations is provided, which includes a base body defining a gripping position at which the center of the substrate is located on a center line extending in a longitudinal direction, a rotary part configured to be rotatable integrally with a second contacting part in a plane where the longitudinal direction intersects with a thickness direction, centering on a supported point provided on a base-end side of the second contacting part on the center line, and movable integrally with the second contacting part. The rotary part and the second contacting part integrally rotate toward the base body centering on the supported point in the plane where the longitudinal direction intersects with the thickness direction, by the second contacting part receiving a reaction force from the substrate when the substrate is gripped.

### TECHNICAL FIELD

The present disclosure relates to a robot hand and a robot having the same.

### BACKGROUND ART

Conventionally, a robot hand which grips a substrate by contacting an edge of the substrate at at least two locations is known. Patent Document 1 discloses a wafer transferring robot as one example of such a robot hand.

Patent Document 1 discloses to advance a mover of an ultrasonic motor toward a tip end of a hand, and push a wafer by a mobile claw toward a fixed claw which is fixed to the robot hand on its tip-end side, so as to grip a circumferential edge of the wafer by the mobile claw and the fixed claw.

### REFERENCE DOCUMENT OF CONVENTIONAL ART

### Patent Document

[Patent Document 1] JP2002-264065A

### DESCRIPTION OF THE DISCLOSURE

### Problem to be Solved by the Disclosure

Meanwhile, the robot hand disclosed in Patent Document 1 and other conventional robot hands are generally provided with a base body. The base body defines a center line extending from a base-end side to a tip-end side at the center in a width direction, and a gripping position at which the center of the substrate is located on the center line.

Then, when the conventional robot hand grips the substrate, a part of the robot hand, which pushes the substrate (e.g., the mobile claw in Patent Document 1), receives a reaction force from the substrate and moves to separate from the base body. Accordingly, the conventional robot hand may not be able to certainly grip the substrate.

Therefore, one purpose of the present disclosure is to provide a robot hand and a robot having the robot hand, capable of certainly gripping a substrate.

### SUMMARY OF THE DISCLOSURE

In order to solve the problem, according to one aspect of the present disclosure, a robot hand configured to grip a substrate by contacting an edge of the substrate at at least two locations is provided. The robot hand includes a base body defining a longitudinal direction connecting a base end to a tip end thereof, a width direction orthogonal to the longitudinal direction, a thickness direction orthogonal to the longitudinal direction and the width direction, a center line extending in the longitudinal direction at the center in the width direction, and a gripping position at which the center of the substrate is located on the center line extending in the longitudinal direction, a first contacting part provided to the base body at the tip-end side and configured to contact a first part of the edge of the substrate when the substrate is gripped, a second contacting part provided on the base-end side of the base body and configured to contact a second part of the edge of the substrate on the center line extending in the longitudinal direction when the substrate is gripped, a rotary part configured to be rotatable integrally with the second contacting part in a plane where the longitudinal direction intersects with the thickness direction, centering on a supported point provided on the base-end side of the second contacting part on the center line extending in the longitudinal direction, and movable integrally with the second contacting part, and a mobile body having a supporting point provided on the base-end side of the rotary part on the center line extending in the longitudinal direction and configured to support the supported point so that the rotary part is rotatable centering on the supported point in the plane where the longitudinal direction intersects with the thickness direction, and configured to, upon the substrate being gripped, move toward the tip end on the center line extending in the longitudinal direction to push the supported point by the supporting point and move the rotary part and the second contacting part toward the tip end. The rotary part and the second contacting part integrally rotate toward the base body centering on the supported point in the plane where the longitudinal direction intersects with the thickness direction, by the second contacting part receiving a reaction force from the substrate when the substrate is gripped.

According to this configuration, the rotary part and the second contacting part integrally rotate toward the base body centering on the supported point in the plane where the longitudinal direction intersects with the thickness direction, by the second contacting part receiving the reaction force from the substrate. Thus, the second contacting part can be prevented from being moved to separate from the base body by receiving the reaction force from the substrate when the substrate is gripped. As a result, the robot hand according to the present disclosure can certainly grip the substrate.

Both of the second contacting part and the rotary body may be included in the same member.

According to this configuration, the robot hand according to the present disclosure can have a simple structure.

The robot hand may further include a rotary member having a circular edge, and a shaft hole bored at the center thereof when seen in the thickness direction. The second contacting part may be a part of the circular edge of the rotary member. The rotary part may be a part of the rotary member on a center side of the circular edge. The supported point may be a part of an inner wall of the shaft hole of the rotary member. The mobile body may have a shaft part to be inserted into the shaft hole of the rotary member to rotatably support the rotary member in a plane where the longitudinal direction intersects with the width direction. The supported point may be a part of an outer surface of the shaft part.

According to this configuration, the edge of the substrate can be prevented from being worn down due to the contact with the second contacting part.

The rotary member may have a first part in a circumferential direction on a side of the base body in the thickness direction. The mobile body may have a second part provided to face to the first part on the base-end side of the shaft part and outward of the first part in a radial direction of the rotary member. The first part may contact the second part by the second contacting part receiving the reaction force from the substrate when the substrate is gripped.

According to this configuration, by the first part of the rotary member contacting with the second part of the mobile body, the rotary member can be prevented from being moved along the shaft member when the second contacting part of the rotary member is in the steady state where the reaction force is not applied from the substrate.

The supporting point may be a rotational shaft of a hinge.

According to this configuration, the robot hand according to the present disclosure can have a simple structure.

The rotary part may have one opposing part linearly extending from the supported point toward the base body when seen in the width direction. The mobile body may have the other opposing part linearly extending from the supporting point toward the base body when seen in the width direction, and opposed to the one opposing part. When seen in the width direction, the one opposing part and the other opposing part may linearly extend in a mutually inclining manner so as to separate from each other as approaching the base body from the supported point and the supporting point, respectively. Upon the substrate being gripped, the one opposing part may rotate toward the other opposing part centering on the supported point.

For example, in the thickness direction, an application point of the reaction force from the substrate to the second contacting part may differ from an application point of a thrust that moves the mobile body toward the tip end on the center line extending in the longitudinal direction.

The base body may have a base part provided on the base-end side thereof, and at least two base-branch parts branching from the base part and extending toward the tip end. The second contacting part may be provided near or in contact with a principal surface of the base part, and the first contacting part may be provided protrudingly from a principal surface of each of the at least two base-branch parts.

According to this configuration, since the at least two first contacting parts contact the tip-end side of the substrate, the substrate can be gripped more certainly.

The substrate may be a semiconductor wafer in a disc-shape. The first contacting part may have an arc-shape corresponding to the edge of the semiconductor wafer when seen in the thickness direction.

According to this configuration, the edge of the substrate can be prevented from being worn down due to the contact with the first contacting part. Moreover, since a contacting area of the first contacting part with the substrate increases, the substrate can be gripped further certainly.

The first contacting part may be a part of an engaging member configured to engage with the first part of the edge of the substrate when the substrate is gripped.

According to this configuration, since the first contacting part can engage with the first part of the edge of the substrate, the substrate can be gripped further certainly.

In order to solve the problem, according to another aspect of the present disclosure, a robot is provided, which includes any one of the robot hands described above and a robotic arm to which the robot hand is attached at a tip end of the robotic arm. The robot changes at least a posture of the robotic arm to transfer the substrate while the robot hand grips the substrate.

According to this configuration, since the robot according to the present disclosure includes the robot hand described above, it can certainly grip the substrate.

### Effect of the Disclosure

According to the present disclosure, a robot hand and a robot having the robot hand, capable of certainly gripping a substrate can be provided.

### BRIEF DESCRIPTION OF DRAWINGS

FIG. 1 is a schematic view illustrating the entire configuration of a robot system according to one embodiment of the present disclosure.

FIG. 2 is a schematic view of a robot hand according to this embodiment of the present disclosure when seen in a thickness direction.

FIG. 3 is a cross-sectional view illustrating an engaging member of the robot hand according to this embodiment of the present disclosure, taken along a line III-III in FIG. 2.

FIG. 4 is a cross-sectional view illustrating a guiding member of the robot hand according to this embodiment of the present disclosure, taken along a line IV-IV in FIG. 2.

FIGS. 5(A) and 5(B) are schematic views illustrating a situation where the robot hand according to this embodiment of the present disclosure grips a semiconductor wafer placed vertically, where FIG. 5(A) illustrates a state before the semiconductor wafer is gripped, and FIG. 5(B) illustrates a state where the semiconductor wafer is gripped and lifted.

FIGS. 6(A) to 6(C) are enlarged cross-sectional views illustrating a situation before a second contacting part receives a reaction force from the semiconductor wafer upon the robot hand according to this embodiment of the present disclosure gripping the semiconductor wafer, where FIG. 6(A) illustrates a mobile body, a rotary member, and their peripheral part, FIG. 6(B) illustrates a shaft member, the rotary member, and their peripheral part, and FIG. 6(C) illustrates a supported point, a supporting point, and their peripheral part.

FIGS. 7(A) to 7(C) are enlarged cross-sectional views illustrating a state where the second contacting part receives the reaction force from the semiconductor wafer when the robot hand according to this embodiment of the present disclosure grips the semiconductor wafer, where FIG. 7(A) illustrates the mobile body, the rotary member, and their peripheral part, FIG. 7(B) illustrates the shaft member, the rotary member, and their peripheral part, and FIG. 7(C) illustrates the supported point, the supporting point, and their peripheral part.

FIGS. 8(A) and 8(B) are schematic views of a situation, when seen from above, where the robot system according to this embodiment of the present disclosure takes the semiconductor wafer accommodated in an accommodating device to the outside, where FIG. 8(A) illustrates an initial state, and FIG. 8(B) illustrates a state where the robot hand is rotated to extend vertically.

FIGS. 9(A) and 9(B) are schematic views of a situation, when seen from above, where the robot system according to this embodiment of the present disclosure takes the semiconductor wafer accommodated in the accommodating device to the outside, where FIG. 9(A) illustrates a state where the semiconductor wafer is gripped by the robot hand, and FIG. 9(B) illustrates a state where the semiconductor wafer is taken out.

FIG. 10 is an enlarged cross-sectional view illustrating a shaft member and its peripheral part of a robot hand according to Modification 1 of this embodiment of the present disclosure.

FIGS. 11(A) and 11(B) are enlarged views of a supported point, a supporting point, and their peripheral part in a state before a second contacting part receives a reaction force from a semiconductor wafer upon a robot hand according to Modification 2 of this embodiment of the present disclosure gripping the semiconductor wafer, where FIG. 11(A) is an external perspective view, and FIG. 11(B) is a cross-sectional view.

FIGS. 12(A) and 12(B) are enlarged views of the supported point, the supporting point, and their peripheral part in a state where the second contacting part receives the reaction force from the semiconductor wafer when the robot hand according to the modification of this embodiment of the present disclosure grips the semiconductor wafer, where FIG. 12(A) is an external perspective view, and FIG. 12(B) is a cross-sectional view.

FIG. 13 is a schematic view illustrating behavior of a mobile body, a rotary member, and their peripheral part in a state where a second contacting part receives a reaction force from a semiconductor wafer when a conventional robot hand grips the semiconductor wafer.

### MODE FOR CARRYING OUT THE DISCLOSURE

Hereinafter, a robot hand, a robot and a robot system having the robot hand according to one embodiment of the present disclosure, are described with reference to the accompanying drawings. Note that this embodiment does not limit the present disclosure. Moreover, below, the same reference characters are given to the same or corresponding elements throughout the drawings to omit redundant description.

### (Robot System 10)

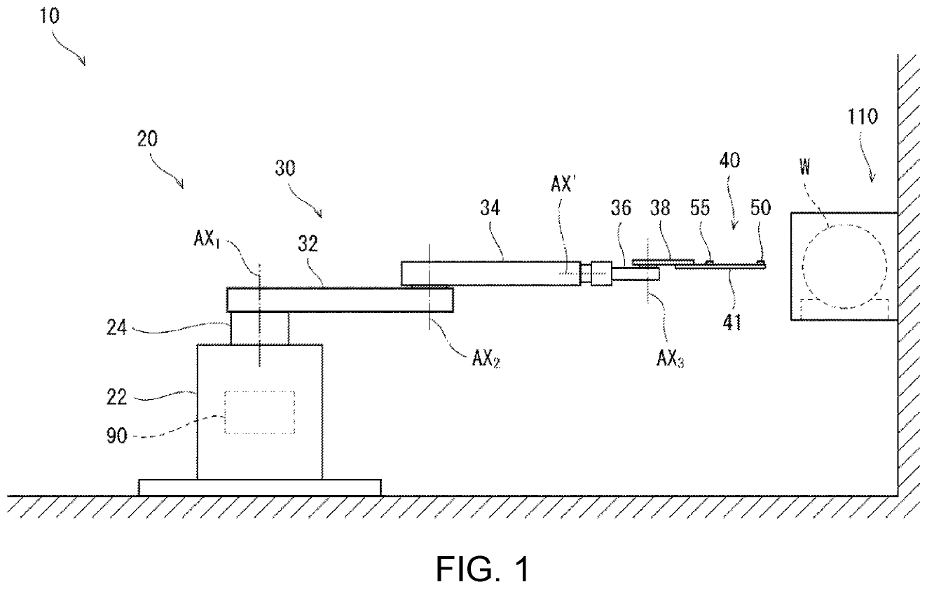

FIG. 1 is a schematic view illustrating the entire configuration of the robot system according to this embodiment. As illustrated in FIG. 1, a robot system 10 according to this embodiment is provided with a robot 20 which transfers a semiconductor wafer W (a substrate) in a disc-shape by gripping it, and an accommodating device 110 which accommodates the semiconductor wafer W.

### (Robot 20)

As illustrated in FIG. 1, the robot 20 according to this embodiment is a horizontally articulated 3-axis robot having a turnable wrist part 36, and is provided with three joint axes. The robot 20 includes a pedestal 22, and a lifting shaft 24 provided to an upper surface of the pedestal 22 and vertically expandable and contractible. The lifting shaft 24 is comprised of, for example, an air cylinder (not illustrated) so as to be expandable and contractible.

Moreover, the robot 20 is further provided with a robotic arm 30 attached to an upper-end part of the lifting shaft 24, a robot hand 40 attached to a tip-end part of the robotic arm 30, and a robot controlling device 90 which controls operation of the robotic arm 30 and the robot hand 40.

### (Robotic Arm 30)

The robotic arm 30 has a first link 32 extending horizontally, a second link 34 coupled to a tip-end part of the first link 32 and extending horizontally, the wrist part 36 coupled to a tip-end part of the second link 34, and a hand-base part 38 coupled to a tip-end part of the wrist part 36.

The first link 32 is coupled at its base-end part to the upper-end part of the lifting shaft 24 via a joint axis which is driven by a servomotor (not illustrated). Therefore, the first link 32 is rotatable about a first axial line AX₁ vertically extending and passing through an axial center of the lifting shaft 24.

The second link 34 is coupled at its base-end part to the tip-end part of the first link 32 via a joint axis which is driven by a servomotor (not illustrated). Therefore, the second link 34 is rotatable about a second axial line AX₂ vertically extending and passing through the tip-end part of the first link 32.

The wrist part 36 is coupled at its base-end part to the tip-end part of the second link 34 via a turning axis which is driven by a servomotor (not illustrated). Therefore, the wrist part 36 is turnable about a turning axial line AX′ horizontally extending and passing through an axial center of the second link 34.

The hand-base part 38 is coupled at its base-end part to the tip-end part of the wrist part 36 via a joint axis AX₃ which is driven by a servomotor (not illustrated). Therefore, the hand-base part 38 is rotatable about a third axial line AX₃ vertically extending and passing through the tip-end part of the wrist part 36.

### (Robot Hand 40)

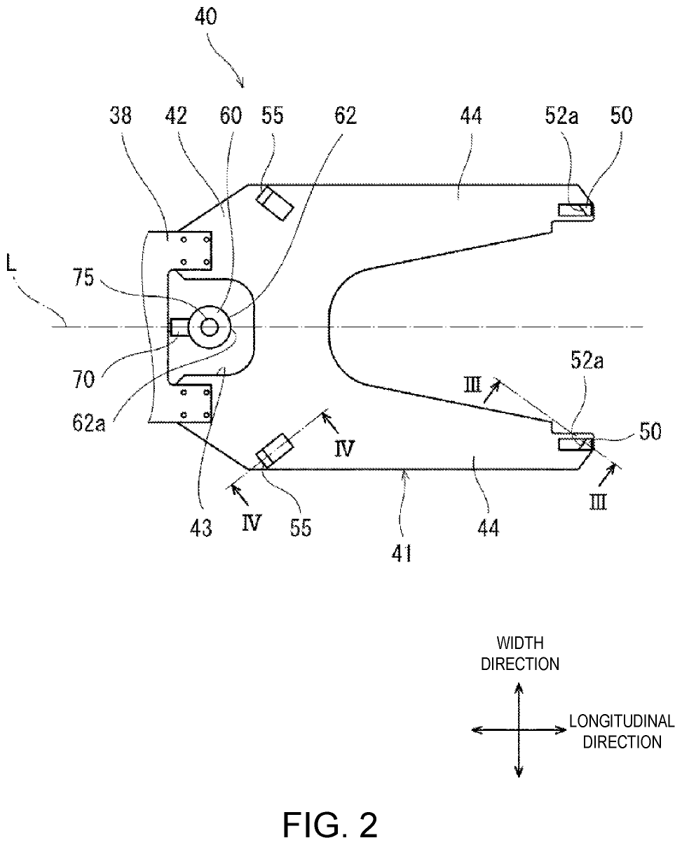

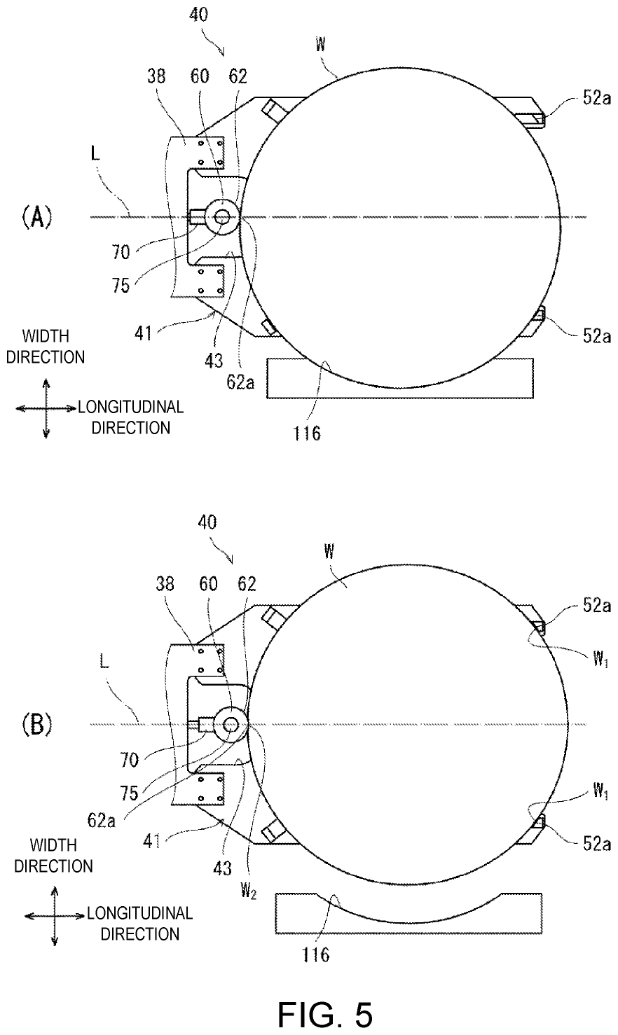

FIG. 2 is a schematic view of the robot hand according to this embodiment, when seen in a thickness direction. As illustrated in FIG. 2, the robot hand 40 according to this embodiment is attached to a tip-end part of the hand-base part 38. The robot hand 40 has a base body 41 defining a longitudinal direction connecting its base end to its tip end, a width direction orthogonal to the longitudinal direction, and the thickness direction orthogonal to the longitudinal direction and the width direction. The base body 41 further defines a center line L extending in the longitudinal direction at the center in the width direction, and a gripping position at which the center of the semiconductor wafer W is located on the center line L (see FIG. 5(B)).

The base body 41 has a base part 42 provided to a base-end side thereof, and two base-branch parts 44 branched from the base part 42 so as to extend toward the tip end. The base part 42 and the two base-branch parts 44 are integrally formed. Moreover, a rectangular notch 43 when seen in the thickness direction is formed on a base-end side of the base part 42. By the base body 41 being structured as described above, it has a substantially Y-shape when seen in the thickness direction.

The robot hand 40 further includes engaging members 50 provided protrudingly from tip-end parts of principal surfaces of the two base-branch parts 44 so as to engage with first parts W₁ (see FIG. 5(B)) on an edge of the semiconductor wafer W, respectively, and guiding members 55 provided protrudingly from both edge parts in the width direction of a principal surface of the base part 42, respectively.

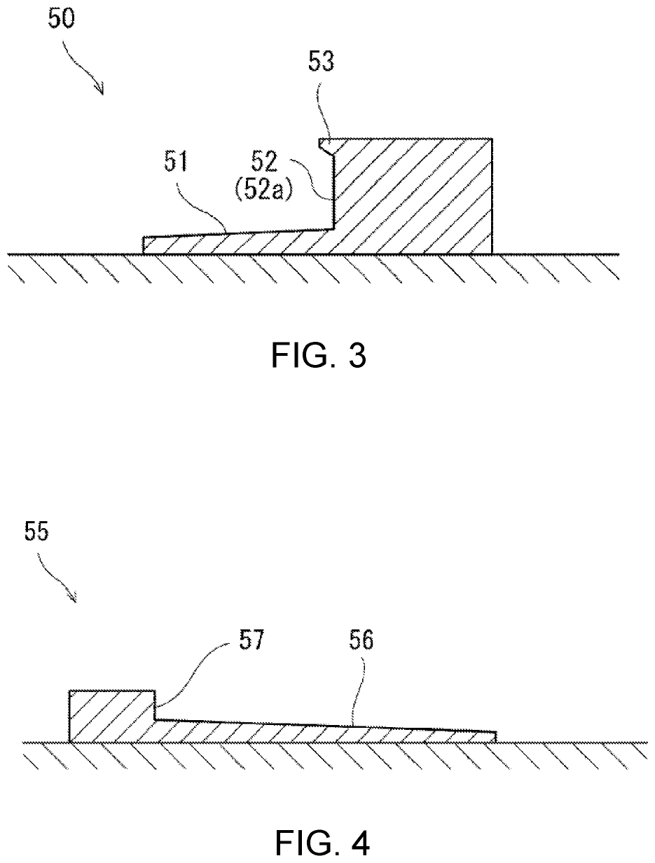

FIG. 3 is a cross-sectional view illustrating the engaging member of the robot hand according to this embodiment, taken along a line III-III in FIG. 2. Each of the two engaging members 50 is fixedly provided to the principal surface of the corresponding base-branch part 44. Note that, as illustrated in FIG. 2, the shapes of the two engaging members 50 are line-symmetry with respect to the center line L. Therefore, here, only one engaging member 50 is described, and similar description of the other engaging member 50 is not repeated.

As illustrated in FIG. 3, the engaging member 50 has an inclining surface 51 inclining to separate from the principal surface of the base-branch part 44 toward the tip end of the principal surface of the base-branch part 44, a standing surface 52 bent from a tip end of the inclining surface 51 so as to stand in the thickness direction of the base body 41, and a flange 53 provided protrudingly from an upper end of the standing surface 52 toward the base end of the base body 41.

In this embodiment, when the semiconductor wafer W is gripped, the standing surface 52 constitutes a first contacting part 52a which contacts the first part W₁ of the edge of the semiconductor wafer W (see FIG. 5(B)). The first contacting part 52a (and the standing surface 52) has an arc-shape when seen in the thickness direction of the base body 41, corresponding to the edge of the semiconductor wafer W.

FIG. 4 is a cross-sectional view illustrating the guiding member of the robot hand according to this embodiment, taken along a line Iv-Iv in FIG. 2. The two guiding members 55 are fixedly provided to the principal surface of the base part 42. Note that, as illustrated in FIG. 2, the shapes of the two guiding members 55 are line-symmetry with respect to the center line L. Therefore, here, only one guiding member 55 is described, and similar description of the other guiding member 55 is not repeated.

As illustrated in FIG. 4, the guiding member 55 has an inclining surface 56 inclining to approach the principal surface of the base part 42 toward the tip end of the principal surface of the base part 42, a standing surface 57 bent from a tip end of the inclining surface 56 so as to stand in the thickness direction of the base body 41.

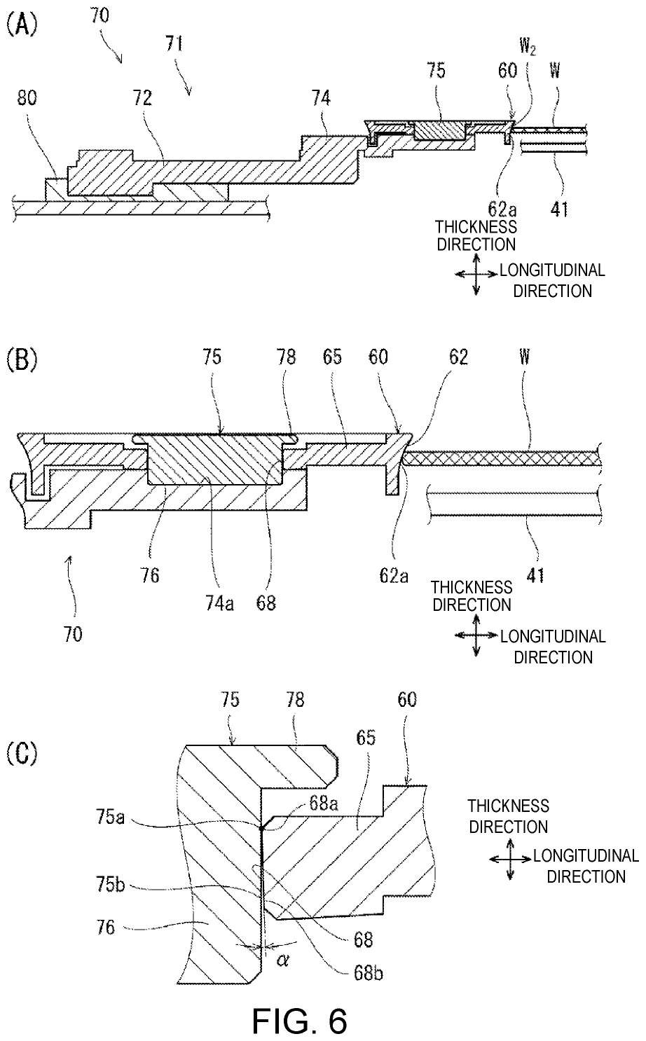

FIGS. 5(A) and 5(B) are schematic views illustrating a situation where the robot hand according to this embodiment grips the vertically placed semiconductor wafer, where FIG. 5(A) illustrates a state before the semiconductor wafer is gripped, and FIG. 5(B) illustrates a state where the semiconductor wafer is gripped and lifted. FIGS. 6(A) to 6(C) are enlarged cross-sectional views illustrating a situation before a second contacting part receives a reaction force from the semiconductor wafer upon the robot hand according to this embodiment gripping the semiconductor wafer, where FIG. 6(A) illustrates a mobile body, a rotary member, and their peripheral part, and FIG. 6(B) illustrates a shaft member, the rotary member, and their peripheral part. Note that FIGS. 6(A) and 6(B) are cross-sectional views when the robot hand 40 is cut in the thickness direction at the position of the center line L illustrated in FIG. 2 and FIGS. 5(A) and 5(B).

As illustrated in FIGS. 5(A), 5(B), and 6(A) to 6(C), the robot hand 40 is further provided with a rotary member 60 provided near the principal surface of the base part 42, and a mobile body 70 reciprocatable along the center line L. The rotary member 60 and the mobile body 70 are each provided on the center line L.

The rotary member 60 has a circular edge 62, and a shaft hole 68 is bored at the center of the rotary member 60 when seen in the thickness direction of the base body 41 (i.e., when seen as illustrated in FIGS. 5(A) and 5(B)). The circular edge 62 extends in the thickness direction of the base body 41 from an end part on the base body 41 side, and then, it further extends in the thickness direction of the base body 41 while curving toward the tip end of the base body 41 when seen in the width direction of the base body 41.

In the robot hand 40 according to this embodiment, since the circular edge 62 of the rotary member 60 has the shape as described above, a second part W₂ of the gripped semiconductor wafer W is restricted to move in a direction separating from the base body 41 in the thickness direction. Moreover, since each of the two engaging members 50 has the flange 53, the two engaging members 50 engage with the first parts W₁ of the gripped semiconductor wafer W, respectively. According to this structure, the robot hand 40 can stably grip the semiconductor wafer W.

In this embodiment, when the semiconductor wafer W is gripped, a part of the circular edge 62 of the rotary member 60 constitutes a second contacting part 62a which contacts the second part W₂ of the edge of the semiconductor wafer W (see FIG. 5(B)) on the center line L. Moreover, in this embodiment, a part of the rotary member 60 on the center side of the circular edge 62 constitutes a rotary part 65 integrally movable with the second contacting part 62a. Therefore, in this embodiment, the second contacting part 62a and the rotary part 65 are both included in the rotary member 60 (in the same member). Moreover, the rotary part 65 is provided on the base-end side of the second contacting part 62a on the center line L, and is movable integrally with the second contacting part 62a.

Moreover, a part of an inner wall of the shaft hole 68 of the rotary member 60 constitutes a supported point 68a (described later), and one opposing part 68b (described later) linearly extending from the supported point 68a toward the base body 41, when seen in the width direction of the base body 41.

As illustrated in FIGS. 6(A) to 6(C), the mobile body 70 has a mobile member 71, and a shaft member 75 (a shaft part) fixed to a tip-end part of the mobile member 71. Here, as illustrated in FIGS. 6(A) to 6(C), the robot hand 40 is further provided with a rail member 80 provided on the opposite side from the rotary member 60 and the shaft member 75 with respect to the base body 41 in the thickness direction of the base body 41, and an actuator (not illustrated) which drives the mobile member 71.

The rail member 80 extends along the center line L, and a base-end part of the mobile member 71 is slidably attached thereto. The actuator may be configured to have, for example, an electric motor and a power transmission mechanism (e.g., a rack and pinion, or a ball screw), or comprised of a pneumatic cylinder, a hydraulic cylinder, etc. Operation of the actuator is controlled by the robot controlling device 90. The actuator may be supported by the hand-base part 38 to which the robot hand 40 is attached.

The mobile member 71 has a first part 72 attached at its base-end part to the rail member 80 and extending along the center line L, and a second part 74 extending along the center line L from an upper surface of a tip-end part of the first part 72. Then, a base-end part of the shaft member 75 is coupled to a concave part 74a formed in an upper surface of a tip-end part of the second part 74. The concave part 74a and the shaft member 75 are each provided to overlap with the notch 43 formed in the base part 42 when seen in the thickness direction of the base body 41 (i.e., when seen as illustrated in FIGS. 5(A) and 5(B)).

The second part 74 of the mobile member 71 is provided so that its upper surface is positioned on the opposite side from the rail member 80 with respect to the base body 41 in the thickness direction of the base body 41. According to the above structure, the mobile member 71 (and the shaft member 75 and the rotary member 60) is reciprocatable along the center line L without obstruction by the base body 41 and the other members. Moreover, according to the above structure, an application point of the reaction force R from the semiconductor wafer W to the second contacting part 62a differs from an application point of a thrust T which moves the mobile body 70 toward the tip end on the center line L, in the thickness direction of the base body 41.

The shaft member 75 has a main shaft part 76 coupled at its base-end part to the concave part 74a of the mobile member 71, and a flange 78 radially protruding from an upper end of the main shaft part 76. The main shaft part 76 of the shaft member 75 has a uniform diameter in the thickness direction of the base body 41. Moreover, this diameter corresponds to the diameter of the shaft hole 68 of the rotary member 60. A diameter of the flange 78 of the shaft member 75 is larger than that of the shaft hole 68 of the rotary member 60.

An outer surface of the shaft member 75 extends in the thickness direction of the base body 41. Then, a part of the outer surface of the shaft member 75 constitutes a supporting point 75a (described later), and the other opposing part 75b (described later) linearly extending from the supporting point 75a toward the base body 41, when seen in the width direction of the base body 41.

In this embodiment, by the main shaft part 76 of the shaft member 75 being inserted into the shaft hole 68 of the rotary member 60, a movable range of the rotary member 60 with respect to the shaft member 75 in a plane where the longitudinal direction and the width direction intersect with each other, is regulated. Moreover, since an edge part of the shaft hole 68 of the rotary member 60 is sandwiched between an edge part of the concave part 74a of the mobile member 71 and the flange 78 of the shaft member 75, a movable range of the rotary member 60 with respect to the shaft member 75 in the thickness direction is regulated.

As illustrated in FIG. 6(C), when the robot hand 40 is in an steady state, the supporting point 75a of the shaft member 75 supports the supported point 68a so that the rotary member 60 is rotatable centering on the supported point 68a in the plane where the longitudinal direction and the thickness direction of the base body 41 intersect with each other.

Then, the one opposing part 68b of the rotary member 60 inclines by an angle “α” with respect to the other opposing part 75b of the shaft member 75. In other words, when seen in the width direction of the base body 41, the one opposing part 68b and the other opposing part 75b linearly extend in a mutually inclining manner so as to separate from each other as approaching the base body 41 from the supported point 68a and the supporting point 75a, respectively.

Upon gripping the semiconductor wafer W, the mobile body 70 moves on the center line L toward the tip end to push the supported point 68a of the rotary member 60 by the supporting point 75a of the shaft member 75, and move the rotary member 60 (i.e., the rotary part 65 and the second contacting part 62a) toward the tip end.

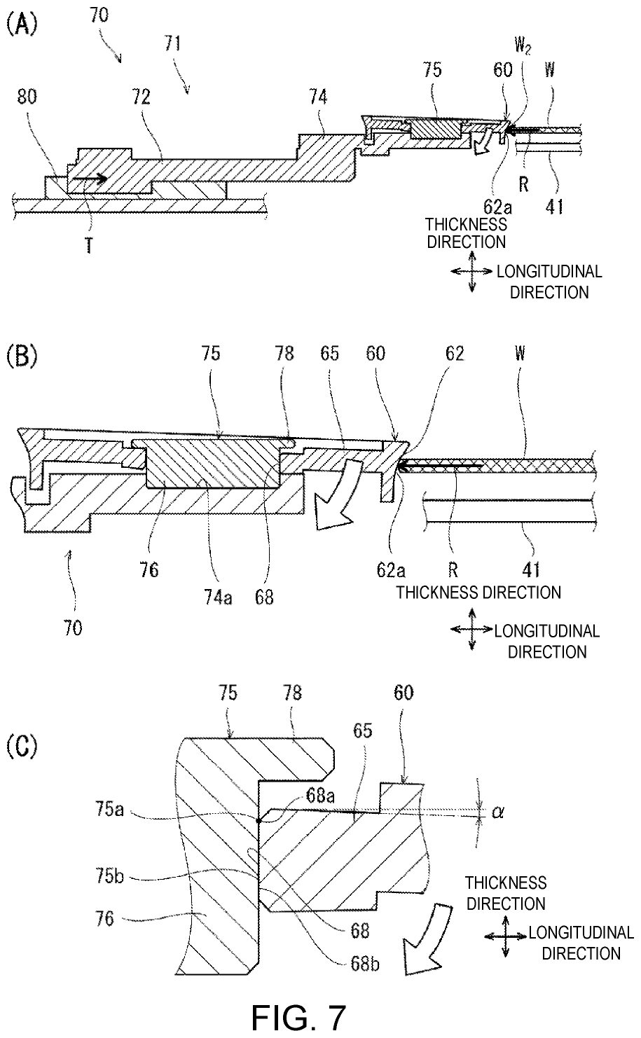

FIGS. 7(A) to 7(C) are enlarged cross-sectional views illustrating a state where the second contacting part receives the reaction force from the semiconductor wafer when the robot hand according to this embodiment grips the semiconductor wafer, where FIG. 7(A) illustrates the mobile body, the rotary member, and their peripheral part, FIG. 7(B) illustrates the shaft member, the rotary member, and their peripheral part, and FIG. 7(C) illustrates the supported point, the supporting point, and their peripheral part.

As illustrated in FIGS. 7(A) to 7(C), when the semiconductor wafer W is gripped, the second contacting part 62a of the rotary member 60 receives the reaction force R from the semiconductor wafer W. Accordingly, as indicated by white arrows in the drawings, the rotary member 60 rotates toward the base body 41 centering on the supported point 68a in the plane where the longitudinal direction and the thickness direction of the base body 41 intersect with each other. In other words, the rotary part 65 and the second contacting part 62a integrally rotate centering on the supported point 68a toward the base body 41 in the plane where the longitudinal direction and the thickness direction of the base body 41 intersect with each other.

Further in other words, the one opposing part 68b rotates centering on the supported point 68a toward the other opposing part 75b. Then, by the one opposing part 68b contacting with the supported point 68a, the rotation stops.

### (Robot Controlling Device 90)

The robot controlling device 90 is provided inside the pedestal 22. Although a concrete configuration of the robot controlling device 90 is not particularly limited, it may be implemented by, for example, a known processor (e.g., a CPU) operating in accordance with a program stored in a storage part (e.g., a memory).

### (Accommodating Device 110)

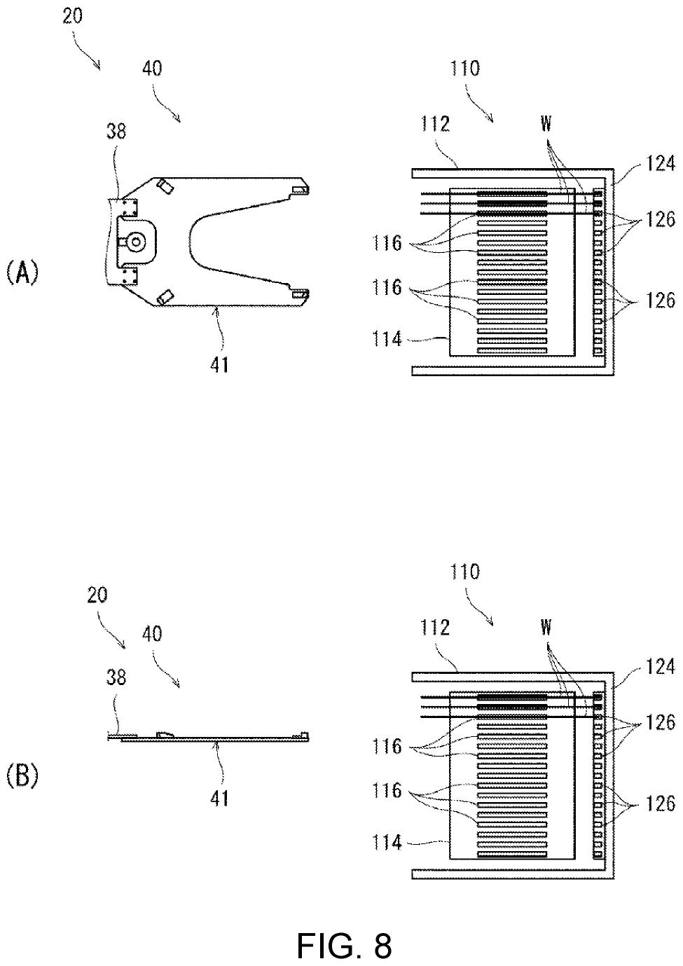

As illustrated in FIG. 1, the accommodating device 110 is provided fixedly on a wall surface at a worksite. Moreover, the accommodating device 110 has a structure to vertically accommodate the semiconductor wafers W so that the semiconductor wafers W extend in the vertical direction. Here, a structure of the accommodating device 110 is described with reference to FIG. 8(A).

FIG. 8(A) is a schematic view illustrating a situation, when seen from above, where the robot system according to this embodiment takes the semiconductor wafer accommodated in the accommodating device to the outside, where FIG. 8(A) illustrates an initial state, and FIG. 8(B) illustrates a state where the robot hand is rotated to extend vertically.

As illustrated in FIG. 8(A), the accommodating device 110 is provided with a shell 112 in a box shape, of which a front surface facing to the robot 20 is opened, and an openable door (not illustrated) provided in front of the shell 112.

A plurality of bottom-plate grooves 116 are formed in an inner surface of a bottom plate 114 of the shell 112. The plurality of bottom-plate grooves 116 each extends in a direction connecting the front surface to a back surface of the shell, and are provided to align in a direction connecting a left surface to a right surface of the shell 112 having an equal interval therebetween (e.g., at 5 mm or above and 15 mm or below). An inner wall of each of the plurality of bottom-plate grooves 116 has, as illustrated in FIGS. 5(A) and 5(B), an arc-shape corresponding to the edge of the semiconductor wafer W, when seen in the direction connecting the left surface to the right surface of the shell 112.

A plurality of back-plate grooves 126 are formed in an inner surface of a back plate 124 of the shell 112. The plurality of back-plate grooves 126 each extends in a direction connecting the bottom surface to an upper surface of the shell 112, and are provided to align in a direction connecting the left surface to the right surface of the shell 112 having an equal interval therebetween (e.g., at 5 mm or above and 15 mm or below). The plurality of back-plate grooves 126 are formed at the same positions as the plurality of bottom-plate grooves 116, in the direction connecting the left surface to the right surface of the shell 112.

According to the structure described above, the accommodating device 110 can fit the edge of the semiconductor wafer W into the bottom-plate groove 116 and the back-plate groove 126 of the shell 112, and thus, a plurality of semiconductor wafers W can be accommodated while being placed vertically.

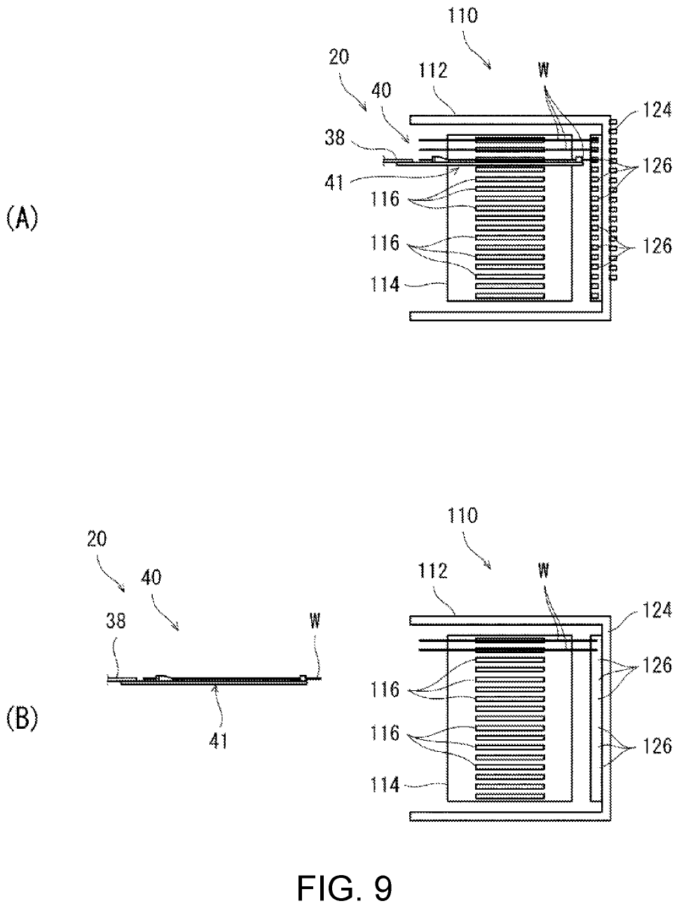

Here, referring to FIGS. 8(A), 8(B), 9(A), and 9(B), one example of a process of taking the semiconductor wafer W vertically accommodated in the accommodating device 110, out of the accommodating device 110, is described. As described above, FIG. 8(A) illustrates the situation where the semiconductor wafer accommodated in the accommodating device is taken out, from the initial state to a state before the wrist part being turned. FIGS. 9(A) and 9(B) are schematic views illustrating a situation, when seen from above, where the robot system according to this embodiment takes the semiconductor wafer accommodated in the accommodating device to the outside, where FIG. 9(A) illustrates a state where the semiconductor wafer is gripped by the robot hand, and FIG. 9(B) illustrates a state where the semiconductor wafer is taken out.

First, the wrist part 36 of the robotic arm 30 is turned from the initial state illustrated in FIG. 8(A) so as to bring the base body 41 of the robot hand 40 to extend vertically as illustrated in FIG. 8(B).

Next, as illustrated in FIG. 9(A), a posture of the robotic arm 30 is changed so that the robot hand 40 is at a position and in a posture grippable of the semiconductor wafer W vertically accommodated in the accommodating device 110. Here, the position and the posture of the robot hand 40 grippable of the semiconductor wafer W vertically accommodated in the accommodating device 110, are a position and a posture where, as illustrated in FIG. 5(A), the standing surfaces 52 of the two engaging members 50, the standing surfaces 57 of the two guiding members 55, and the circular edge 62 of the rotary member 60, are all facing to (or contact) the edge of the semiconductor wafer W.

Then, by the mobile body 70 moving toward the tip end on the center line L, the second contacting part 62a of the rotary member 60 pushes the semiconductor wafer W toward the tip end. Thus, the semiconductor wafer W is pushed by the rotary member 60 from the base-end side of the base body 41 against the standing surfaces 52 of the two engaging members 50. In this manner, the robot hand 40 grips the vertically placed semiconductor wafer W.

Moreover, the robot hand 40 moves, while gripping the semiconductor wafer W, in a direction separating from a position at which the semiconductor wafer W is placed (from the bottom-plate groove 116 in FIG. 5(B)), so that the semiconductor wafer W separates from the bottom-plate groove 116 of the accommodating device 110. This state is illustrated in FIG. 5(B).

Finally, as illustrated in FIG. 9(B), the posture of the robotic arm 30 is changed so as to move the robot hand 40 outside the accommodating device 110. Accordingly, the robot system 10 according to this embodiment can take the semiconductor wafer W vertically accommodated in the accommodating device 110, out of the accommodating device 110.

### Effects

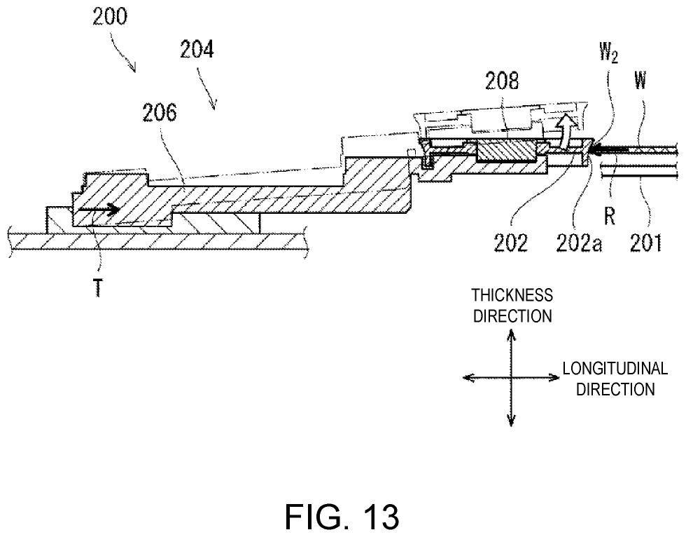

FIG. 13 is a schematic view illustrating behavior of a mobile body, a rotary member, and their peripheral part in a state where a second contacting part receives the reaction force from a semiconductor wafer when a conventional robot hand grips the semiconductor wafer. As illustrated in FIG. 13, when a conventional robot hand 200 grips the semiconductor wafer W, a rotary member 202 pushing the semiconductor wafer W receives the reaction force R from the semiconductor wafer W, and thus, as indicated by a white arrow in the drawing, a mobile body 204 (i.e., a mobile member 206 and a shaft member 208) tends to rotate so as to separate from a base body 201 centering on a base-end part of the mobile body 204. Accompanying to this, a second contacting part 202a of the rotary member 202 moves to separate from the base body 201. As a result, the conventional robot hand 200 may not be able to certainly grip the semiconductor wafer W.

On the other hand, in robot hand 40 according to this embodiment, when the second contacting part 62a of the rotary member 60 receives the reaction force R from the semiconductor wafer W (the substrate), the rotary member 60 (i.e., the rotary part 65 and the second contacting part 62a) integrally rotates centering on the supported point 68a toward the base body 41 in the plane where the longitudinal direction and the thickness direction of the base body 41 intersect with each other. Therefore, the second contacting part 62a can be prevented from being moved to separate from the base body 41 when receiving the reaction force R from the semiconductor wafer W. As a result, the robot hand 40 according to the present disclosure can certainly grip the semiconductor wafer W.

In this embodiment, since the second contacting part 62a and the rotary part 65 are both included in the rotary member 60 (in the same member), the robot hand 40 according to this embodiment can have a simple structure.

In this embodiment, since the second contacting part 62a is configured as a part of the circular edge 62 of the rotary member 60, and the supporting point 75a is configured as a part of the outer surface of the shaft member 75, the edge of the semiconductor wafer W can be prevented from being worn down due to the contact with the second contacting part 62a.

In this embodiment, similar to the conventional robot hand, for example, the application point of the reference force R differs from the application point of the thrust T. Therefore, a moment which rotates the mobile body 70 centering on its base-end part so as to separate from the base body 41, is generated. However, in the robot hand 40 according to this embodiment, the rotary member 60 rotates toward the base body 41 centering on the supported point 68a when the second contacting part 62a of the rotary member 60 receives the reaction force R from the semiconductor wafer W, and thus, the moment can be canceled out.

In this embodiment, the engaging members 50 are provided protrudingly from the principal surfaces of the two base-branch parts 44, respectively. Accordingly, since the two first contacting parts 52a contact the tip-end side of the semiconductor wafer W, the semiconductor wafer W can be gripped more certainly.

In this embodiment, since the first contacting part 52a of the engaging member 50 has an arc-shape corresponding to the edge of the semiconductor wafer W when seen in the thickness direction of the base body 41, the edge of the semiconductor wafer W can be prevented from being worn down due to the contact with the first contacting part 52a. Moreover, since a contacting area of the first contacting part 52a with the semiconductor wafer W increases, the semiconductor wafer W can be gripped further certainly.

In this embodiment, when the semiconductor wafer W is gripped, the first contacting part 52a is configured as a part of the engaging member 50 which engages with the first part W₁ of the edge of the semiconductor wafer W, and it can engage with the first part W₁ of the edge of the semiconductor wafer W. Therefore, the semiconductor wafer W can be gripped further certainly.

Since effects achieved by the robot 20 and the robot system 10 according to this embodiment are the same as those achieved by the robot hand 40, similar description is not repeated here.

### (Modification 1)

It is apparent for a person skilled in the art from the above description that many improvements and other embodiments of the present disclosure are possible. Therefore, the above description is to be interpreted only as illustration, and it is provided in order to teach a person skilled in the art the best mode for implementing the present disclosure. The details of the structures and/or the functions may be substantially changed, without departing from the spirit of the present disclosure.

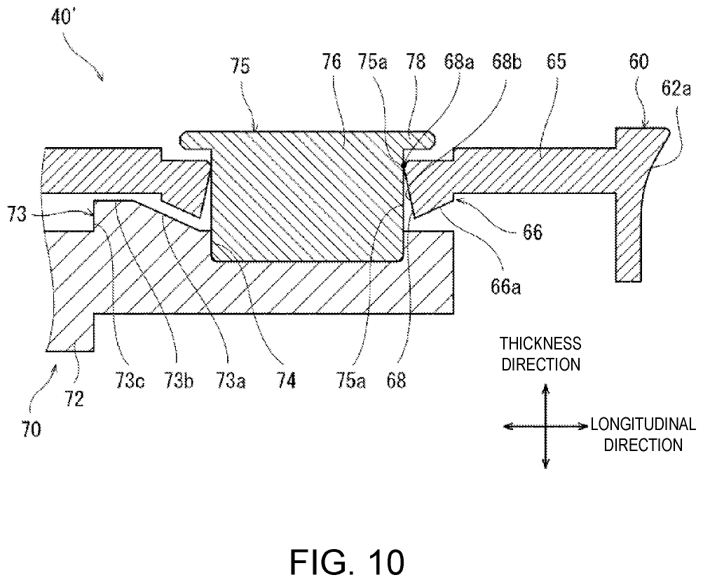

FIG. 10 is an enlarged cross-sectional view illustrating a shaft member and its peripheral part of a robot hand according to Modification 1 of the embodiment described above. Note that the robot hand according to this modification has the same structure as the robot hand 40 according to the embodiment, except for that a first protruding part 66 is provided protrudingly from the rotary member 60, and a second protruding part 73 is provided protrudingly from the mobile member 71. Therefore, the same reference characters are given to the same parts, and similar description is not repeated.

As illustrated in FIG. 10, the rotary member 60 of a robot hand 40′ according to this modification is provided with the first protruding part 66 (a first part) in its circumferential direction on the base body 41 side in the thickness direction of the base body 41. In detail, the first protruding part 66 is provided protrudingly from the edge part of the shaft hole 68 of the rotary member 60 on the base body 41 side, over the entire circumferential area of the rotary member 60.

The first protruding part 66 has a tip-end surface 66a (i.e., a surface opposing to the mobile member 71) inclining to separate from the base body 41 in the thickness direction of the base body 41, as the first protruding part 66 goes outward in the radial direction of the rotary member 60.

In this modification, the mobile body 70 has the second protruding part 73 (a second part) provided to be faced to the first protruding part 66 of the rotary member 60 on the base-end side of the shaft member 75 (the shaft part), at radially outward of the first protruding part 66 of the rotary member 60.

The second protruding part 73 has, when seen in the width direction of the base body 41, an inclining surface 73a which inclines at an obtuse angle with respect to the base body 41 corresponding to the tip-end surface 66a of the first protruding part 66, a top surface 73b bent from an edge part of the inclining surface 73a and extending in the longitudinal direction of the base body 41, and a side surface 73c bent from an edge part of the top surface 73b different from the side of the inclining surface 73a, and extending in the thickness direction of the base body 41 to the mobile member 71.

According to this structure, by the first protruding part 66 of the rotary member 60 contacting with the second protruding part 73 of the mobile body 70, the rotary member 60 can be prevented from being moved along the shaft member 75 when the second contacting part 62a of the rotary member 60 is in the steady state where the reaction force R is not applied from the semiconductor wafer W.

Note that although in this modification the first part of the rotary member 60 is the first protruding part 66, and the second part of the mobile body 70 is the second protruding part 73, it is not limited to this.

For example, the first part of the rotary member 60 may be configured as the first protruding part 66 similar to the modification, and the second part of the mobile body 70 may be configured as a groove having the inclining surface 73a opposing to the first protruding part 66 of the rotary member 60 on the base-end side of the shaft member 75 (the shaft part) at radially outward of the first protruding part 66. Also according to this structure, effects similar to the modification described above can be achieved.

Alternatively, the second part of the mobile body 70 may be configured as the second protruding part 73 similar to the modification, and the first part of the rotary member 60 may be configured as a groove having the tip-end surface 66a. The tip-end surface 66a is provided to the edge part of the shaft hole 68 of the rotary member 60 on the base body 41 side over the entire circumferential area of the rotary member 60, while inclining to separate from the base body 41 in the thickness direction of the base body 41, as it goes outward in the radial direction of the rotary member 60. Also according to this structure, effects similar to the modification described above can be achieved.

### (Modification 2)

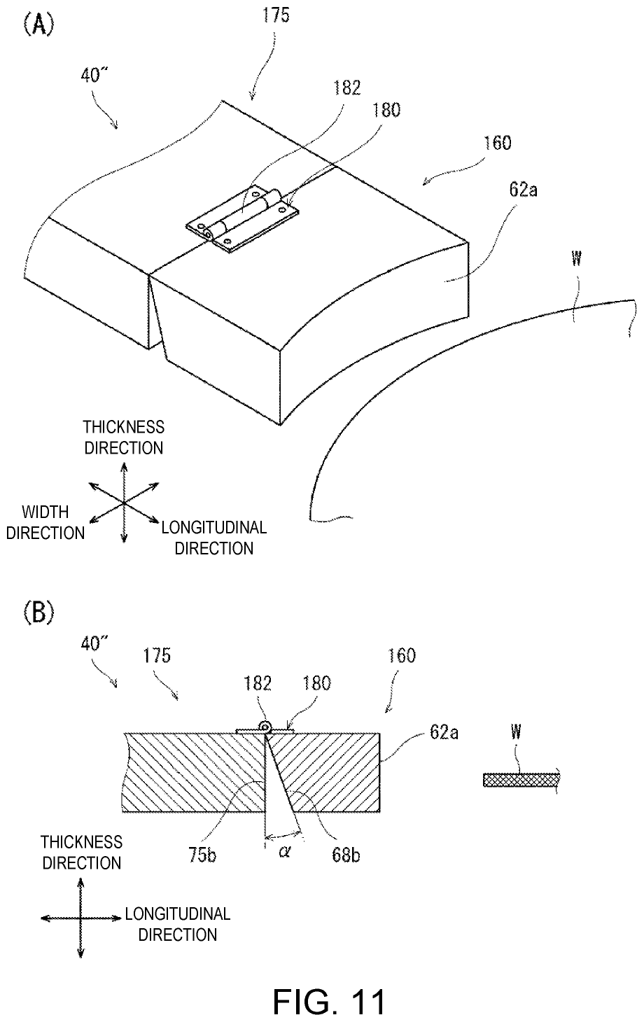

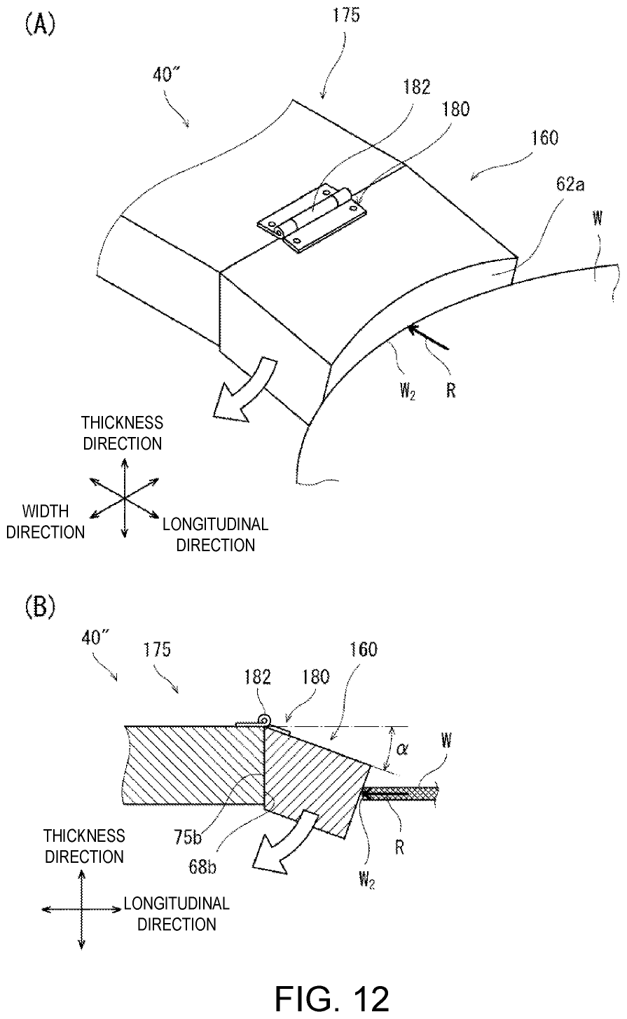

A robot hand according to Modification 2 of the embodiment described above is described with reference to FIGS. 11(A), 11(B), 12(A), and 12(B). Note that the robot hand according to this modification has the same structure as the robot hand 40 according to the embodiment, except for that the robot hand according to this modification is provided with a first member 160 instead of the rotary member 60, and a second member 175 instead of the shaft member 75. Therefore, the same reference characters are given to the same parts, and similar description is not repeated.

FIGS. 11(A) and 11(B) are enlarged views of a supported point, a supporting point, and their peripheral part in a state before the second contacting part receives the reaction force from the semiconductor wafer, upon the robot hand according this modification gripping the semiconductor wafer, where FIG. 11(A) is an external perspective view, and FIG. 11(B) is a cross-sectional view. FIGS. 12(A) and 12(B) are enlarged views of the supported point, the supporting point, and their peripheral part in a state where the second contacting part receives the reaction force from the semiconductor wafer when the robot hand according to this modification grips the semiconductor wafer, where FIG. 12(A) is an external perspective view, and FIG. 12(B) is a cross-sectional view.

As illustrated in FIGS. 11(A), 11(B), 12(A), and 12(B), a robot hand 40″ according to this modification is provided with a first member 160 in a substantially rectangular-parallelepiped shape, and a second member 175 in a substantially rectangular-parallelepiped shape provided on the tip-end side of the base body 41 with respect to the first member 160.

An end edge of a base-end surface of the first member 160 (i.e., a surface on the base-end side of the base body 41) on the side opposite from the base body 41 in the thickness direction of the base body 41, is coupled via a hinge 180 to an end edge of a tip-end surface of the second member 175 (i.e., a surface on the base-end side of the base body 41) on the side opposite from the base body 41 in the thickness direction of the base body 41.

A rotational shaft 182 of the hinge 180 is provided so as to extend along the end edge of the base-end surface of the first member 160 on the opposite side from the base body 41 in the thickness direction of the base body 41 (and along the end edge of the tip-end surface of the second member 175 on the opposite side from the base body 41 in the thickness direction of the base body 41). Then, the one opposing part 68b of the first member 160 inclines by the angle “α” with respect to the other opposing part 75b of the second member 175.

In this modification, a part of a tip-end surface of the first member 160 (i.e., a surface on the tip-end side of the base body 41) constitutes the second contacting part 62a which contacts the second part W₂ of the semiconductor wafer W. Moreover, a part of the first member 160 on the base-end side of the base body 41 with respect to the tip-end surface of the first member 160, constitutes the rotary part 65. Furthermore, the base-end surface of the first member 160 constitutes the one opposing part 68b, and the tip-end surface of the second member 175 constitutes the other opposing part 75b. Then, the rotational shaft 182 of the hinge 180 is configured as the supporting point 75a. Moreover, a part of the first member 160 attached to the rotational shaft 182 of the hinge 180 constitutes the supported point 68a.

According to this structure, when the robot hand 40″ according to this modification grips the semiconductor wafer W as illustrated in FIGS. 12(A) and 12(B), the one opposing part 68b of the first member 160 rotates centering on the supported point 68a toward the other opposing part 75b of the second member 175, by the second contacting part 62a of the first member 160 receiving the reaction force from the semiconductor wafer W. Also according to this mode, the second contacting part 62a can be prevented from being moved to separate from the base body 41 when receiving the reaction force R from the semiconductor wafer W, as indicated by white arrows in the drawings.

Note that in this modification the rotational shaft 182 of the hinge 180 may be biased by a biasing member (e.g., a spring member) in the steady state where the reaction force R is not applied from the semiconductor wafer W, so that the one opposing part 68b of the first member 160 maintains its inclining state with respect to the other opposing part 75b of the second member 175 by the angle “α” when seen in the thickness direction of the base body 41 (i.e., maintains the state illustrated in FIGS. 11(A) and 11(B)).

Moreover, the rotational shaft 182 of the hinge 180 may be configured so that the one opposing part 68b of the first member 160 may not rotate in the direction of increasing the angle larger than “a” illustrated in FIG. 11(B). Therefore, when the second contacting part 62a of the first member 160 is in the steady state where the reaction force R is not applied from the semiconductor wafer W, the first member 160 can be prevented from rotating in the separating direction from the base body 41.

### (Other Modifications)

Although in the embodiment and the modification described above the second contacting part 62a and the rotary body 65 are both included in the rotary member 60 (in the same member), it is not limited to this. That is, the second contacting part 62a and the rotary body 65 may be included in separate members, as long as they can move integrally.

Although in the embodiment and the modification described above the shaft member 75 is coupled to the mobile member 71, it is not limited to this. For example, the mobile member 71 and the shaft member 75 may be integrally formed so that the entire mobile body 70 is comprised of a single member. In other words, the mobile body 70 may have a mobile part, and a shaft part which is formed integrally with the mobile part.

Although in the embodiment and the modification described above the first contacting part 52a is a part of the engaging member 50 which engages with the first part W₁ of the semiconductor wafer W, it is not limited to this. For example, the first contacting part 52a may be formed in a rectangular-parallelepiped shape, or a cube shape, and may be comprised of a member which only contacts the first part W₁ of the semiconductor wafer W without engaging therewith.

Although in the embodiment and the modification described above the second contacting part 62a is provided near the principal surface of the base part 42, it is not limited to this. That is, the second contacting part 62a may be provided in contact with the principal surface of the base part 42.

Although in the embodiment and the modification described above the base body 41 has the base part 42, and the base-branch parts 44 formed integrally with the base part 42, it is not limited to this. For example, the base body 41 may not have the base-branch parts 44 by not being branched at its tip-end side, but may be provided with one or more first contacting parts 52a at the tip-end side of the principal surface of the base body 41. Alternatively, the base body 41 may be provided with the base part 42 and three or more base-branch parts 44 formed integrally with the base part 42, and the first contacting part 52a may be provided to the principal surface of each of the three or more base-branch parts 44.

Although in the embodiment and the modifications described above the substrate is the semiconductor wafer W in the disc-shape, it is not limited to this. For example, the substrate may be a semiconductor wafer in a rectangular plate-shape when seen in its thickness direction, a semiconductor wafer in another shape, or a substrate other than a semiconductor wafer.

Although in the embodiment and the modifications described above the robot 20 is the horizontally articulated 3-axis robot having the turnable wrist part 36, it is not limited to this. For example, the robot 20 may not have the turnable wrist part 36, or may be configured as a horizontally articulated robot with one, two, or four or more axes. Alternatively, the robot 20 may be configured as a polar coordinate robot, a cylindrical coordinate robot, a Cartesian coordinate robot, a vertically articulated robot, or another robot.

Although in the embodiment and the modifications described above the accommodating device 110 has a structure in which the semiconductor wafer W is vertically accommodated so as to extend in the vertical direction, it is not limited to this. For example, the accommodating device 110 may have a structure in which the semiconductor wafer W is horizontally accommodated so as to extend in the horizontal direction.

Although in the embodiment and the modifications described above the robot system 10 is provided with the accommodating device 110 which accommodates the semiconductor wafer W (the substrate), it is not limited to this. For example, the robot system 10 may not have the accommodating device 110, but may have a plurality of processing devices which apply processing to the semiconductor wafer W. Then, the robot system 10 may transfer the semiconductor wafer W by the robot 20 between the plurality of processing devices while gripping it. Note that the processing applied to the semiconductor wafer W by the plurality of processing devices may be, for example, heat treatment, impurity introduction, thin-film formation, lithography processing, cleaning, etching, or other processings.

### DESCRIPTION OF REFERENCE CHARACTERS

10 Robot System
20 Robot
22 Pedestal
24 Lifting Shaft
30 Robotic Arm
32 First Link
34 Second Link
36 Wrist Part
38 Hand-base Part
40 Robot Hand
41 Base Body
42 Base Part
43 Notch
44 Base-branch Part
50 Engaging Member
51 Inclining Surface
52 Standing Surface
52a First Contacting Part
53 Flange
55 Guiding Member
56 Inclining Surface
57 Standing Surface
60 Rotary Member
62 Circular Edge
62a Second Contacting Part
65 Rotary Part
66 First Protruding Part
66a Tip-end Surface
68 Shaft Hole
68a Supported Point
68b One Opposing Part
70 Mobile Body
71 Mobile Member
72 First Part
73 Second Protruding Part
73a Inclining Surface
73b Top Surface
73c Side Surface
74 Second Part
74a Concave Part
75 Shaft Member
75a Supporting Point
75b Other Opposing Part
76 Main Shaft Part
78 Flange
80 Rail Member
90 Robot Controlling Device
110 Accommodating Device
112 Shell
114 Bottom Plate
116 Bottom-plate Groove
124 Back Plate
126 Back-plate Groove
160 First Member
175 Second Member
180 Hinge
182 Rotational Shaft
200 Conventional Robot Hand
201 Base Body
202 Rotary Member
202a Second Contacting Part
204 Mobile Body
206 Mobile Member
208 Shaft Member
AX₁ First Axial Line
AX₂ Second Axial Line
AX₃ Third Axial Line
AX′ Turning Axial Line
W Semiconductor Wafer
W₁ First Part

1. A robot hand configured to grip a substrate by contacting an edge of the substrate at at least two locations, comprising:
a base body defining a longitudinal direction connecting a base end to a tip end thereof, a width direction orthogonal to the longitudinal direction, a thickness direction orthogonal to the longitudinal direction and the width direction, a center line extending in the longitudinal direction at the center in the width direction, and a gripping position at which the center of the substrate is located on the center line extending in the longitudinal direction;
a first contacting part provided to the base body at the tip-end side and configured to contact a first part of the edge of the substrate when the substrate is gripped;
a second contacting part provided on the base-end side of the base body and configured to contact a second part of the edge of the substrate on the center line extending in the longitudinal direction when the substrate is gripped;
a rotary part configured to be rotatable integrally with the second contacting part in a plane where the longitudinal direction intersects with the thickness direction, centering on a supported point provided on the base-end side of the second contacting part on the center line extending in the longitudinal direction, and movable integrally with the second contacting part; and
a mobile body having a supporting point provided on the base-end side of the rotary part on the center line extending in the longitudinal direction and configured to support the supported point so that the rotary part is rotatable centering on the supported point in the plane where the longitudinal direction intersects with the thickness direction, and configured to, upon the substrate being gripped, move toward the tip end on the center line extending in the longitudinal direction to push the supported point by the supporting point and move the rotary part and the second contacting part toward the tip end,
wherein the rotary part and the second contacting part integrally rotate toward the base body centering on the supported point in the plane where the longitudinal direction intersects with the thickness direction, by the second contacting part receiving a reaction force from the substrate when the substrate is gripped.

2. The robot hand of claim 1, wherein both of the second contacting part and the rotary part are included in the same member.

3. The robot hand of claim 2, further comprising a rotary member having a circular edge, and a shaft hole bored at the center thereof when seen in the thickness direction,
wherein the second contacting part is a part of the circular edge of the rotary member,
wherein the rotary part is a part of the rotary member on a center side of the circular edge,
wherein the supported point is a part of an inner wall of the shaft hole of the rotary member,
wherein the mobile body has a shaft part to be inserted into the shaft hole of the rotary member to rotatably support the rotary member in a plane where the longitudinal direction intersects with the width direction, and
wherein the supported point is a part of an outer surface of the shaft part.

4. The robot hand of claim 3, wherein the rotary member has a first part in a circumferential direction on a side of the base body in the thickness direction,
wherein the mobile body has a second part provided to face to the first part on the base-end side of the shaft part and outward of the first part in a radial direction of the rotary member, and
wherein the first part contacts the second part by the second contacting part receiving the reaction force from the substrate when the substrate is gripped.

5. The robot hand of claim 1, wherein the supporting point is a rotational shaft of a hinge.

6. The robot hand of claim 1, wherein the rotary part has one opposing part linearly extending from the supported point toward the base body when seen in the width direction,
wherein the mobile body has the other opposing part linearly extending from the supporting point toward the base body when seen in the width direction, and opposed to the one opposing part,
wherein when seen in the width direction, the one opposing part and the other opposing part linearly extend in a mutually inclining manner so as to separate from each other as approaching the base body from the supported point and the supporting point, respectively, and upon the substrate being gripped, the one opposing part rotates toward the other opposing part centering on the supported point.

7. The robot hand of claim 1, wherein, in the thickness direction, an application point of the reaction force from the substrate to the second contacting part differs from an application point of a thrust that moves the mobile body toward the tip end on the center line extending in the longitudinal direction.

8. The robot hand of claim 1, wherein the base body has a base part provided on the base-end side thereof, and at least two base-branch parts branching from the base part and extending toward the tip end, and
wherein the second contacting part is provided near or in contact with a principal surface of the base part, and the first contacting part is provided protrudingly from a principal surface of each of the at least two base-branch parts.

9. The robot hand of claim 1, wherein the substrate is a semiconductor wafer in a disc-shape, and
wherein the first contacting part has an arc-shape corresponding to the edge of the semiconductor wafer when seen in the thickness direction.

10. The robot hand of claim 1, wherein the first contacting part is a part of a first engaging member configured to engage with the first part of the edge of the substrate when the substrate is gripped.

11. A robot, comprising:
the robot hand of claim 1; and
a robotic arm to which the robot hand is attached at a tip end of the robotic arm,
wherein the robot changes at least a posture of the robotic arm to transfer the substrate while the robot hand grips the substrate.
